(19) United States
(12) Patent Application Publication
(10) Pub. No.: US 2012/0119734 A1
(43) Pub. Date: May 17, 2012

(54) HALL INTEGRATED CIRCUIT USING RECTIFIER CIRCUIT

(75) Inventor: Dong Ok HAN, Suwon (KR)

(73) Assignee: SAMSUNG ELECTRO-MECHANICS CO., LTD., Gyunggi-do (KR)

(21) Appl. No.: 13/027,776

(22) Filed: Feb. 15, 2011

(30) Foreign Application Priority Data
Nov. 15, 2010 (KR) 10-2010-0113402

(51) Int. Cl. G01R 33/07

(52) U.S. Cl. 324/251

(57) ABSTRACT

There is provided a hall integrated circuit using a rectifier circuit including: a hall device receiving a power supply voltage for excitation and outputting a hall voltage which is in proportion to the intensity of an applied magnetic field; an amplifier amplifying the hall voltage; and a rectifying unit rectifying the amplified hall voltage to improve sensitivity and modify for user convenience by ensuring a high headroom at even a low power supply voltage.

### CROSS-REFERENCE TO RELATED APPLICATIONS

This application claims the priority of Korean Patent Application No. 10-2010-0113402 filed on Nov. 15, 2010, in the Korean Intellectual Property Office, the disclosure of which is incorporated herein by reference.

### BACKGROUND OF THE INVENTION

1. Field of the Invention

The present invention relates to a hall integrated circuit, and more particularly, to a hall integrated circuit using a rectifier circuit that can improve sensitivity and modify it for user convenience by ensuring a high headroom at even a low power supply voltage by using the rectifier circuit.

2. Description of the Related Art

In general, a hall device senses a magnetic field by using a hall effect. In the case of the hall effect, when the magnetic field is applied to a predetermined conductor on which a current flows, a force (Lorentz force) is generated in a predetermined direction and the flow of the current is changed by the force, and a difference in voltage between two detection terminals (hereinafter, referred to as a “hall voltage”) is generated by the flow change of the current, and a hall sensor can sense the magnetic field by using the hall voltage.

The hall sensor is classified into an omnipolar type hall sensor that senses the intensity of the magnetic field regardless of a type of the magnetic field (an N pole or an S pole) and a bipolar type hall sensor that senses the type and intensity of the magnetic field according to a sensing mode of the magnetic field.

Meanwhile, in recent years, as a low-power integrated circuit (IC) has been needed, a power supply voltage has been gradually lowered. In particular, the omnipolar type hall sensor used in a cellular phone has a problem in that the amplification rate of an amplifier is limited by a low power supply voltage to deteriorate sensitivity.

### SUMMARY OF THE INVENTION

An aspect of the present invention provides a hall integrated circuit using a rectifier circuit that can improve sensitivity and modify it for user convenience by ensuring a high headroom, even with a low power supply voltage.

According to an aspect of the present invention, there is provided a hall integrated circuit using a rectifier circuit, including: a hall device receiving a power supply voltage for excitation and outputting a hall voltage which is in proportion to the intensity of an applied magnetic field; an amplifier amplifying the hall voltage; and a rectifying unit rectifying the amplified hall voltage.

The rectifying unit may include a rectifier that rectifies the amplified hall voltage and controls an output reference level of a hall voltage rectified through a DC bias.

Further, the rectifying unit may further include an amplifier for amplifying the hall voltage of which the output reference level is controlled.

The hall integrated circuit may further include: a comparison unit comparing the rectified hall voltage with a reference voltage and converting the corresponding voltage into a digital signal; and a latch for buffering the digital signal.

Meanwhile, the comparison unit may include a Schmitt trigger or a comparator.

Further, the hall integrated circuit may further include: a clock generating unit; and a polarity determining unit for determining the polarity of the magnetic field on the basis of a reference clock generated by the clock generating unit.

The polarity determining unit may include: a magnetism-pulse converting module generating a pulse signal by a propagation delay on the basis of the reference clock, the power supply voltage, and a first hall voltage and a second hall voltage of the hall device; and a polarity determining module determining the polarity of the magnetic field on the basis of any one of a first voltage generated from the first hall voltage and a second voltage generated from the second hall voltage and the pulse signal and the reference clock.

The magnetism-pulse converting module may include: a first module generating the first voltage from the reference clock, the power supply voltage, and the first hall voltage; a second module generating the second voltage from the reference clock, the power supply voltage, and the second hall voltage; and an XOR operator XOR-operating the first voltage and the second voltage.

The first module may include: a first inverter receiving the power supply voltage and outputting an inverted voltage according to a reference clock; a first switch turned on by applying the first hall voltage; and a first capacitor generating the first voltage by repeating charging and discharging according to the reference clock, and the second module may include: a second inverter receiving the power supply voltage and outputting the inverted voltage according to the reference clock; a second switch turned on by applying the second hall voltage; and a second capacitor generating the second voltage by repeating charging and discharging according to the reference clock.

The polarity determining module may include: an AND operator AND-operating any one of the first voltage and the second voltage and the pulse signal; and an SR flip-flop generating a polarity signal which is set according to an output of the AND operator and reset according to the reference clock.

Meanwhile, a reference voltage of the comparison unit may be controllable through a control terminal for user convenience.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a configuration diagram of a hall integrated circuit according to an exemplary embodiment of the present invention;

FIGS. 2A and 2B are a diagram showing an output waveform before and after rectification, in the case of an omnipolar type according to an exemplary embodiment of the present invention;

FIGS. 3A and 3B are a diagram showing an output waveform before and after rectification in the case of a bipolar type according to an exemplary embodiment of the present invention;

FIGS. 4A to 4C are a configuration diagram of a magnetism-pulse converting module according to an exemplary embodiment of the present invention; and

FIGS. 5A and 5B are a configuration diagram of a polarity determining unit according to an exemplary embodiment of the present invention.

### DETAILED DESCRIPTION OF THE PREFERRED EMBODIMENT

Exemplary embodiments of the present invention will now be described in detail with reference to the accompanying drawings.

The present invention is not limited to the exemplary embodiments and the exemplary embodiments are used to help in understanding the spirit of the present invention. Like reference numerals refer to like elements in the accompanying drawings.

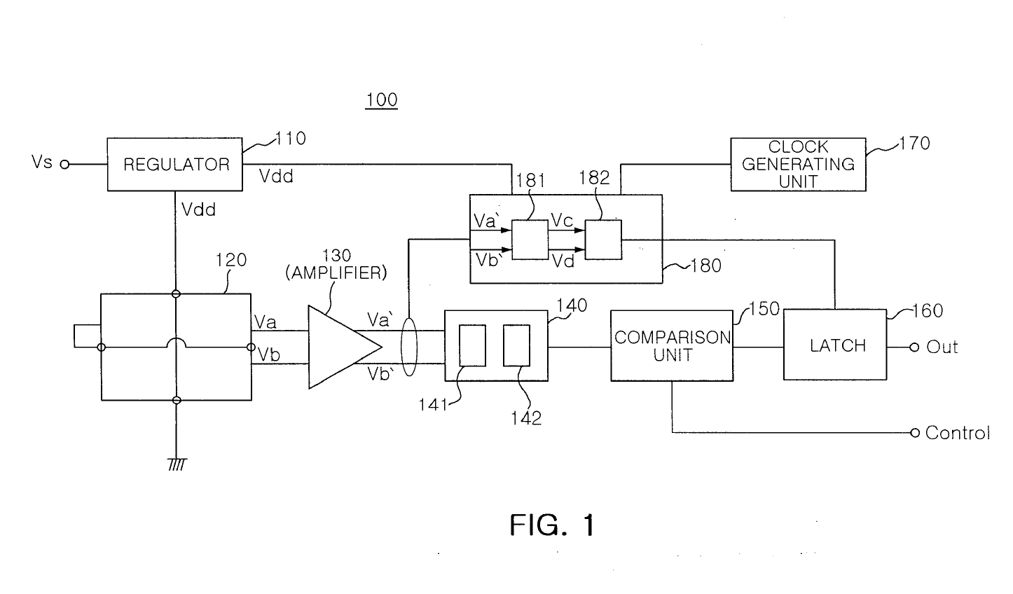

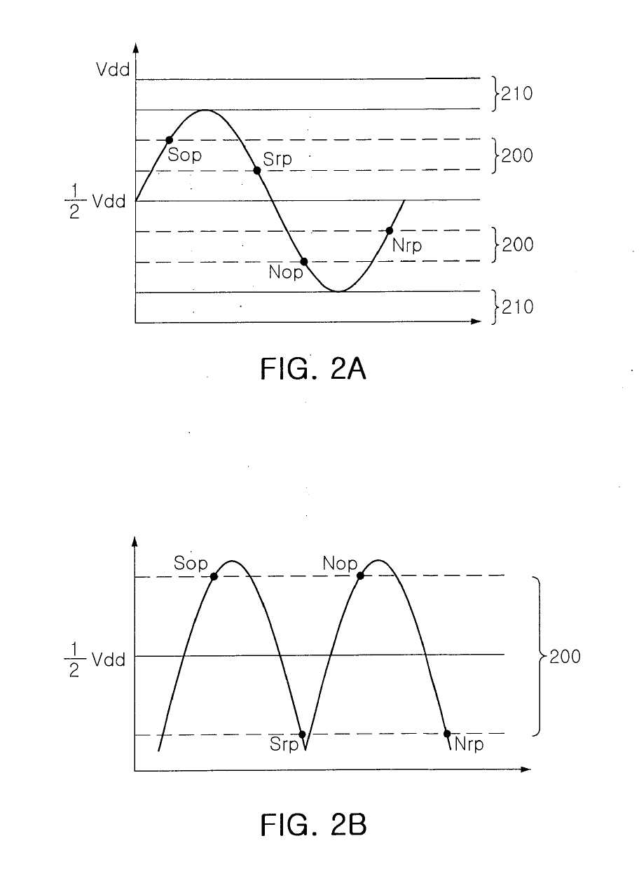

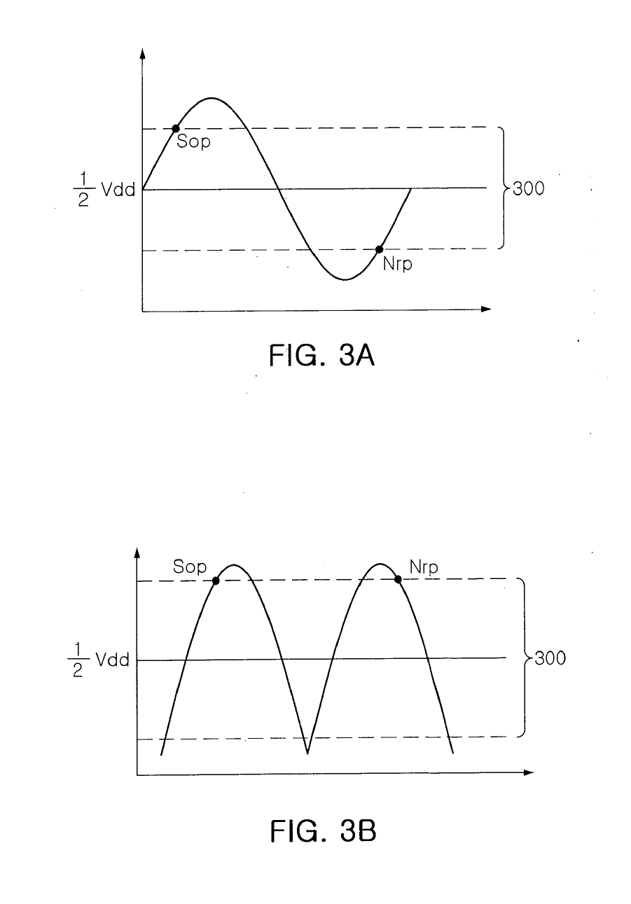

FIG. 1 is a configuration diagram of a hall integrated circuit 100 according to an exemplary embodiment of the present invention, FIGS. 2A to 2B are a diagram showing an output waveform before and after rectification in the case of an omnipolar type according to an exemplary embodiment of the present invention, and FIGS. 3A and 3B are a diagram showing an output waveform before and after rectification in the case of a bipolar type according to an exemplary embodiment of the present invention. The hall integrated circuit 100 according to the exemplary embodiment of the present invention may include a regulator 110, a hall device 120, an amplifier 130, a rectifying unit 140, a comparison unit 150, a latch 160, a clock generating unit 170, and a polarity determining unit 180.

Referring to FIG. 1, the regulator 110 generates a predetermined power supply voltage Vdd without a ripple by receiving an external voltage Vs and the generated power supply voltage Vdd is used to drive blocks in the hall integrated circuit 100.

The hall device 120 receives the power supply voltage Vdd for excitation from the voltage regulator 110 and outputs hall voltages Va and Vb which are in proportion to the intensity of a magnetic field applied from the outside. The outputted hall voltage is transferred to the amplifier 130. The hall voltage may include a first hall voltage Va which increases according to the intensity of the magnetic field and a second hall voltage Vb which decreases according to the intensity of the magnetic field.

The amplifier 130 amplifies the hall voltages Va and Vb outputted from the hall device 120 at a predetermined amplification rate. The amplified hall voltages Va′ and Vb′ are outputted to the rectifying unit 140. The amplifier 130 may include a chopper amplifier.

The rectifying unit 140 may include a rectifier 141 and an amplifier 142, and the amplifier 142 may not be used, according to a configuration of the circuit and as needed.

The rectifier 141 of the rectifying unit 140 receives the amplified hall voltages Va′ and Vb′ and rectifies them on the basis of a voltage common mode (VCM) and controls an output reference level of the rectified hall voltages through an internally set DC bias. The rectified hall voltages of which the output reference level is controlled are transferred to the amplifier 142.

In detail, assuming that the voltage common mode (VCM) of the amplifier 130 is ½ Vdd, the rectifying unit 140 according to the exemplary embodiment of the present invention rectifies the amplified voltage on the basis of ½ Vdd and may control an output reference level of the rectified voltage through the internally set DC bias.

Meanwhile, the amplifier 142 of the rectifying unit 140 additionally amplifies the hall voltage of which the output reference level is controlled and outputs the amplified hall voltage to the comparison unit 150. As such, according to the exemplary embodiment of the present invention, the amplified hall voltage Va′ and Vb′ are rectified, the output reference level of the full-wave rectified voltage is controlled through the internally set DC bias, and the corresponding voltages are amplified through the amplifier 142 so as to ensure a high headroom, thereby improving the sensitivity of the comparison unit 150 connected to a rear end.

Hereafter, referring to FIGS. 2A to 3B, the rectifying unit 140 according to the exemplary embodiment of the present invention will be described in more detail.

FIGS. 2A and 2B are a diagram showing an output waveform rectification in the case of an omnipolar type according to an exemplary embodiment of the present invention and FIGS. 3A and 3B are a diagram showing an output waveform before and after rectification in the case of a bipolar type according to an exemplary embodiment of the present invention.

FIG. 2A is a diagram showing the amplified hall voltages Va′ and Vb′ outputted from the amplifier 130 according to the existing omnipolar type (without the rectifying unit 140 of the present invention). That is, as shown in FIG. 2A, the voltages amplified by the amplifier 130 swing on the basis of the voltage common mode (i.e., ½ Vdd). Thereafter, the amplified voltages are compared with a predetermined reference voltage by the comparison unit 150 including a Schmitt trigger circuit at operating points Sop and Nop and release points Srp and Nrp to generate a digital signal. In the case of using the amplifier 130 using the existing chopping structure as shown in FIG. 2A, a gain of the amplifier 130 is limited due to a limit of a headroom (representing a value acquired by subtracting high and low sidebands 210 from Vdd). In particular, when the hall integrated circuit operates at a low power supply voltage Vdd, a resolution 200 decreases to deteriorate sensitivity. Accordingly, according to the exemplary embodiment of the present invention, by placing the rectifying unit 140 on the rear end of the amplifier 130, it is possible to solve the problems.

In detail, as shown in FIG. 2B, the rectifying unit 140 rectifies the amplified voltage shown in FIG. 2A on the basis of the voltage common mode (½ Vdd) to control an output reference level of the corresponding voltage through the internally set DC bias. Further, a signal output larger than the existing headroom is generated by amplifying the corresponding voltage in the amplifier 142 so as to increase the resolution 200 and remarkably improve sensitivity. Moreover, although an N-pole Schmitt trigger and an S-pole Schmitt trigger were required in the related art, the present invention can be implemented with a single Schmitt trigger, this being advantageous in terms of power consumption or area.

FIG. 3A is a diagram showing the amplified hall voltages Va′ and Vb′ outputted from the amplifier 130 according to the existing bipolar type (without the rectifying unit 140 of the present invention). That is, as shown in FIG. 3A, the voltages amplified by the amplifier 130 swing on the basis of the voltage common mode (i.e., ½ Vdd). Thereafter, the amplified voltages are compared with a predetermined reference voltage by the comparison unit 150 including a Schmitt trigger circuit at operating points Sop and Nop and release points Srp and Nrp to generate a digital signal (Locations of the N pole and the S pole may be exchanged according to the direction of the magnetic field). As such, since the bipolar type operates throughout the N pole and the S pole, the comparison unit 150 may include only one Schmitt trigger unlike the omnipolar type. The bipolar type has a limit depending on headroom, which is reduced, as compared with the omnipolar type. However, the bipolar type still requires the Schmitt trigger having a complicated structure using a hysteresis characteristic. Accordingly, according to the exemplary embodiment of the present invention, it is possible to solve the above-mentioned problem by using a simple comparator instead of the Schmitt trigger using the hysteresis characteristic.

In detail, as shown in FIG. 3B, the rectifier 141 rectifies the amplified voltage shown in FIG. 3A on the basis of the voltage common mode (½ Vdd) to control an output reference level of the corresponding voltage through the internally set DC bias. The operating point Sop and the release point Nrp may be set at the same level through rectification and the same digital signal as that of the existing bipolar type may be generated by configuring the comparison unit 150 using one simple comparator. Similarly, it is possible to further increase a resolution 300 by adding the amplifier 142 to the rectifying unit 140, and as a result, it is possible to further improve the sensitivity. As described above, although full-wave rectification has been primarily described in the exemplary embodiment of the present invention, it may be modified to half-wave rectification.

Meanwhile, the comparison unit 150 compares the hall voltage outputted from the rectifying unit 140 with a reference voltage to convert the corresponding voltage into the digital signal. The converted digital signal is outputted to the latch 160. As described above, the omnipolar type may include the Schmitt trigger circuit having the hysteresis characteristic and the bipolar type may include the simple comparator.

Further, the comparison unit 150 may output a comparison value through a predetermined reference voltage. The reference voltage may be controlled through an external terminal (control terminal) as shown in FIG. 1. By this configuration, by changing the operating point and the release point, an additional function of adjusting the sensitivity according to user convenience may be performed. Further, the magnitude of the reference voltage of the comparison unit 150 is controllable so as to reduce a design burden of the Schmitt trigger circuit used in the bipolar type.

The latch 160 receives and buffers the digital signal outputted from the comparison unit 150. Further, the latch 160 receives and buffers a polarity of a magnetic field outputted from the polarity determining unit 180 to be described below.

Meanwhile, hereinafter, the clock generating unit 170 and the polarity determining unit 180 will be described. When the hall integrated circuit according to the exemplary embodiment of the present invention is applied to a brushless DC motor (BLDC), it is necessary to determine the polarity of the magnetic field in addition to the intensity of the magnetic field. Accordingly, the bipolar type needs to additionally have the polarity determining unit 180 to be described below.

The clock generating unit 170 generates a reference clock having a predetermined cycle and the generated reference clock is used to show a characteristic which a system desires and may be used by the polarity determining unit 180.

The polarity determining unit 180 may include a magnetism-pulse converting module 181 converting an inputted magnetic field into a pulse signal and a polarity determining module 182 determining the polarity of the magnetic field on the basis of the pulse signal. The polarity determining unit 180 having such a structure determines the polarity of the magnetic field on the basis of the reference clock outputted from the clock generating unit 170 and the amplified hall voltages Va′ and Vb′ outputted from the amplifier 130. In FIG. 1, the hall voltages Va′ and Vb′ outputted from the amplifier 130 are inputted, but depending on the exemplary embodiment, the hall voltages Va and Vb may be inputted directly from the hall device 120.

Hereinafter, the magnetism-pulse converting module 181 and the polarity determining module 182 of the polarity determining unit 180 will be described in more detail.

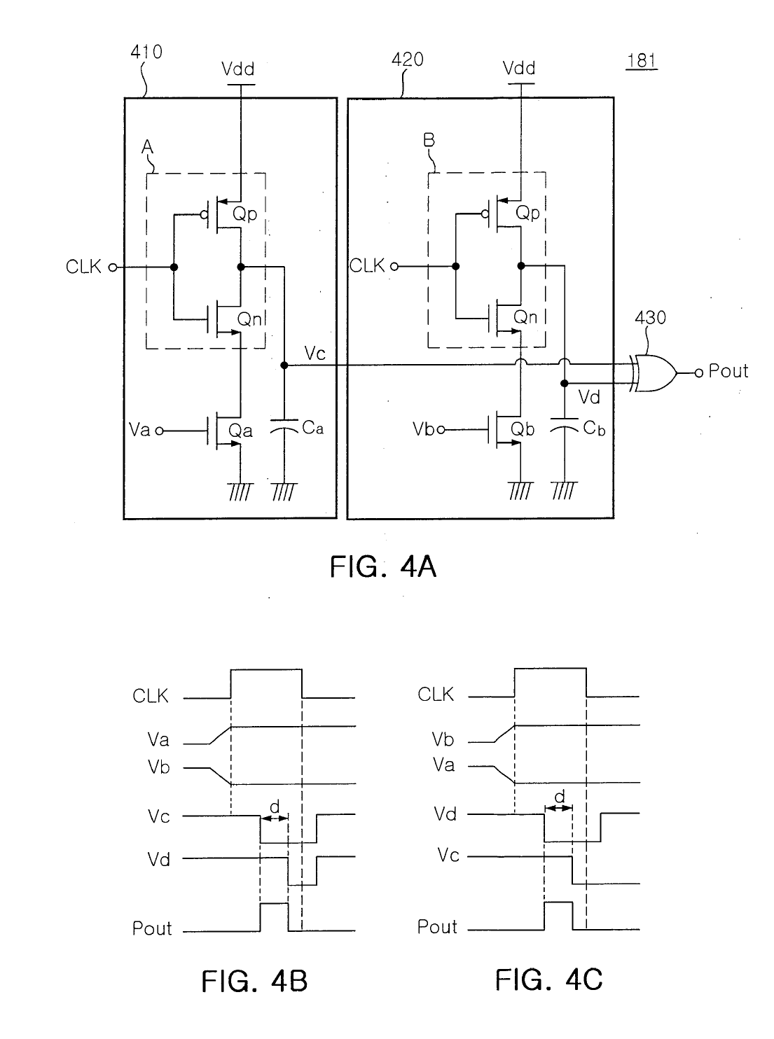

FIGS. 4A to 4C are a configuration diagram of a magnetism-pulse converting module according to an exemplary embodiment of the present invention.

Referring to FIG. 4A, the magnetism-pulse converting module 181 may include a first module 410 including a first inverter A connected to the power supply voltage Vdd, a first metal oxide semiconductor field-effect transistor (MOSFET) Qa connected between the first inverter A and a ground, and a first capacitor Ca connected between the first inverter A and the ground, a second module 420 including a second inverter B connected to the power supply voltage Vdd, a second MOSFET Qb connected between the second inverter B and the ground, and a second capacitor Cb connected between the second inverter B and the ground, and a logic element XOR 430. When a reference clock CLK is low (L), an upper MOSFET Qp of the inverter A or B is turned on and when the reference clock CLK is high (H), it is determined whether the inverter A or B is turned on depending on the first MOSFET Qa and the second MOSFET Qb.

Further, each of the inverters A and B having the same configuration includes a P-type MOSFET Qp of which a source is connected to the power supply voltage Vdd and a drain is connected to a drain of an N-type MOSFET Qn, and an N-type MOSFET Qn of which the drain is connected to the drain of the P-type MOSFET Qp and a source is connected to a drain of the first MOSFET Qa, and gates of the MOSFETs Qp and Qn are connected to a common gate. The reference clock CLK outputted from the clock generating unit 170 is inputted into the common gate. Meanwhile, a first voltage Vc charged in the first capacitor Ca and a second voltage Vb charged in the second capacitor Cb are connected to an input terminal of the logic element XOR and a pulse signal Pout is outputted from the logic element XOR.

Hereinafter, a process of generating the pulse signal from the magnetism-pulse converting module 181 having such a structure will be described.

First, it is assumed that a magnetic filed having an S polarity is applied. Referring to FIGS. 4A and 4B, while the reference clock CLK is low (L), the P-type MOSFET Qp is turned on. Accordingly, the first voltage Vc and the second voltage Vd are charged with Vdd-Vds by the power supply voltage Vdd. Herein, Vds represents a drain-source voltage of the P-type MOSFET Qp. Meanwhile, when the power supply voltage Vdd is applied to the hall device 120 and the magnetic field is formed, the hall output voltages Va and Vd are different from each other by the intensity of the magnetic field applied at the same voltage. In this case, the first MOSFET Qa and the second MOSFET Qb connected to Va and Vb are turned on and the first MOSFET Qa may be substituted by an equivalent resistance R1 and the second MOSFET Qb may be substituted by an equivalent resistance R2. The magnitude of the equivalent resistance R1 or R2 may be determined on the basis of the gate-source voltage applied to each of the MOSFETs Qa and Qb.

When the reference clock CLK increases from the low level to the high level, the P-type MOSFET Qp is turned off and the N-type MOSFET Qn is turned on. Accordingly, the voltage Vdd-Vds charged in the capacitor C is each discharged through the N-type MOSFET Qn and the first MOSFET Qa, and a delay d shown in the figure is generated between the first voltage Vc and the second voltage Vd by a propagation delay based on each of the equivalent resistances R1 and R2, in detail, based on a difference in power consumption which occurs by a voltage difference between Va and Vb. The delay d is outputted as the pulse signal Pout through the logic element XOR.

Next, it is first assumed that a magnetic field having an N polarity is applied. In this case, as shown in the figure, waveforms of the first hall voltage Va and the second hall voltage Vb are reversed and waveforms of the first voltage Vc and the second voltage Vd are reversed. Hereinafter, it will be described in detail.

Referring to FIGS. 4A and 4C, while the reference clock CLK is low (L), the P-type MOSFET Qp is turned on: Accordingly, the first voltage Vc and the second voltage Vd are charged with Vdd-Vds by the power supply voltage Vdd. Herein, Vds represents the drain-source voltage of the P-type MOSFET Qp. Meanwhile, when the power supply voltage Vdd is applied to the hall device 120 and the magnetic field is formed, the hall output voltages Va and Vd are different from each other due to the intensity of the magnetic field applied at the same voltage. In this case, the first MOSFET Qa and the second MOSFET Qb connected to Va and Vb are turned on and in this case, the first MOSFET Qa may be substituted by an equivalent resistance R1 and the second MOSFET Qb may be substituted by an equivalent resistance R2. The magnitude of the equivalent resistance R1 or R2 may be determined on the basis of the gate-source voltage applied to each of the MOSFETs Qa and Qb.

When the reference clock CLK increases from the low level to the high level, the P-type MOSFET Qp is turned off and the N-type MOSFET Qn is turned on. Accordingly, the voltage Vdd-Vds charged in the capacitor C is each discharged through the N-type MOSFET Qn and the first MOSFET Qa and a delay d shown in the figure is generated between the first voltage Vc and the second voltage Vd by a propagation delay based on each of the equivalent resistances R1 and R2, in detail, based on a difference in power consumption which occurs by a voltage difference between Va and Vb. The delay D is outputted as the pulse signal Pout through the logic element XOR. Meanwhile, the N pole and S pole are used for ease of description and since they may be changed depending on an input direction of the magnetic field, the N pole and the S pole may operate opposite to each other.

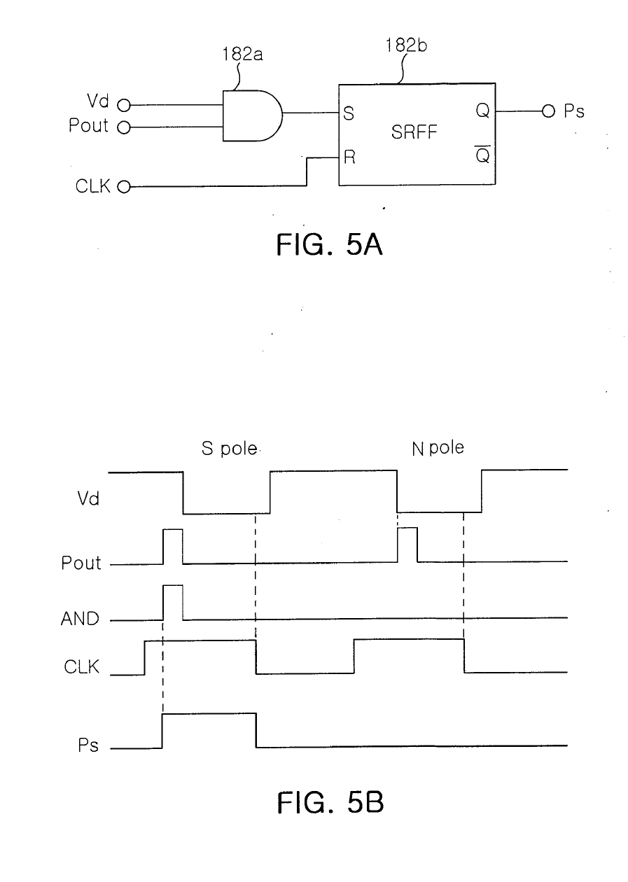

Meanwhile, FIGS. 5A and 5B are a configuration diagram of a polarity determining module according to an exemplary embodiment of the present invention and FIG. 5A is a block diagram of the polarity determining module 182 and FIG. 5B is a waveform diagram of a principal part of the polarity determining module 182.

Hereinafter, referring to FIGS. 5A and 5B, a process of determining the polarity of the magnetic field according to the configuration of FIG. 4A will be described in detail.

First, as shown in FIG. 5B, when it is assumed that the magnetic field having the S pole is applied, the second voltage Vd and the pulse signal Pout are inputted into a logic element (AND gate) 182a. At the time when both the second voltage Vd and the pulse signal Pout are high (H), a high (H) signal is outputted from the logic element (AND gate) 182a and the outputted high (H) signal is inputted into a terminal S of an SR flip-flop (SRFF). In this case, a polarity signal Ps outputted from a terminal Q of the SR flip-flop (SRFF) is at the high level (H). Thereafter, the polarity signal Ps is at the low level (L) at the time when the reference clock CLK is at the low level (L).

Next, when it is assumed that the magnetic field having the N pole is applied, the second voltage Vd and the pulse signal Pout are inputted into the logic element (AND gate) 182a. Since the second voltage Vd is 0 when the magnetic field having the N pole is applied, unlike the case in which the magnetic field having the S pole is applied, a low (L) signal is outputted from the logic element (AND gate) and the output low (L) signal is inputted into the terminal S of the SR flip-flop (SRFF). In this case, the polarity signal Ps outputted from the terminal Q of the SR flip-flop (SRFF) is still at the low level (L). Accordingly, by the configuration shown in FIG. 4A, the polarity of the magnetic field applied to the hall device 120 is S.

According to the same operational principle, in the case where the first voltage Vc is applied to the input terminal of the logic element 182a instead of the second voltage Vd in FIG. 5A, the polarity of the magnetic field applied from the polarity signal Ps outputted from the SR flip-flop 182b is N.

Hereinafter, an operation of a hall integrate circuit according to an exemplary embodiment of the present invention will be described. A detailed description of the parts described in detail in FIGS. 1 to 5B will be omitted.

Referring to FIGS. 1 to 5B, the power supply voltage Vdd generated by the regulator 110 is outputted to the hall device 120 and the polarity determining unit 180. As described in detail above, the polarity determining unit 180 can be applied to the bipolar type.

As the power supply voltage Vdd is applied, the hall device 120 is excited and thereafter, when the magnetic field is applied from the outside, the hall voltages Va and Vb are outputted from the hall device 120. The hall voltages Va and Vb outputted from the hall device 120 are transferred to the amplifier 130.

The amplifier 130 amplifies the hall voltages Va and Vb at a predetermined amplification rate and transfers the amplified hall voltages Va′ and Vb′ to the rectifying unit 140. The amplifier 130 may include a chopper amplifier.

Thereafter, the rectifying unit 140 receives the amplified hall voltages Va′ and Vb′ and rectifies them on the basis of a voltage common mode (VCM) and controls an output reference level of the rectified hall voltages through an internally set DC bias. The rectified hall voltages of which the output reference level is controlled are transferred to the amplifier 142. Thereafter, the amplifier 142 additionally amplifies the hall voltage of which the output reference level is controlled and outputs the amplified hall voltage to the comparison unit 150. As such, according to the exemplary embodiment of the present invention, the amplified hall voltages Va′ and Vb′ are rectified, the output reference level of the rectified voltage is controlled through the DC bias, and the corresponding voltages are amplified through the amplifier 142 so as to ensure a high headroom, thereby improving the sensitivity of the comparison unit 150 connected to a rear end.

Thereafter, the comparison unit 150 compares the rectified hall voltage outputted from the rectifying unit 140 with a predetermined reference voltage or a reference voltage which is controllable through the external terminal (control terminal) shown in FIG. 1 for user convenience and converts the corresponding voltage into the digital signal. The converted digital signal is outputted to the latch 160.

Lastly, the latch 160 receives and buffers the digital signal outputted from the comparison unit 150. Further, the latch 160 receives and buffers the polarity of the magnetic field outputted from the polarity determining unit 180 to be described below.

Meanwhile, as described above, the bipolar type may further include the polarity determining unit 180.

As described above, the polarity determining unit 180 may include the magnetism-pulse converting module 181 and the polarity determining module 182 determining the polarity of the magnetic field on the basis of the pulse signal. The polarity determining unit 180 having such a structure determines the polarity of the magnetic field on the basis of the reference clock outputted from the clock generating unit 170 and the amplified hall voltages Va′ and Vb′ outputted from the amplifier 130.

As set forth above, it is possible to improve sensitivity and modify for user convenience by ensuring a high headroom at even a low power supply voltage by using a full-wave rectifying circuit.

While the present invention has been shown and described in connection with the exemplary embodiments, it will be apparent to those skilled in the art that modifications and variations can be made without departing from the spirit and scope of the invention as defined by the appended claims.

Accordingly, the scope of the present invention will be determined by the appended claims.

What is claimed is:

1. A hall integrated circuit, comprising:
a hall device receiving a power supply voltage for excitation and outputting a hall voltage which is in proportion to the intensity of an applied magnetic field;
an amplifier amplifying the hall voltage; and
a rectifying unit rectifying the amplified hall voltage.

2. The hall integrated circuit of claim 1, wherein the rectifying unit includes a rectifier that rectifies the amplified hall voltage and controls an output reference level of a hall voltage rectified through a DC bias.

3. The hall integrated circuit of claim 2, wherein the rectifying unit further includes an amplifier for amplifying the hall voltage of which the output reference level is controlled.

4. The hall integrated circuit of claim 2, further comprising:
a comparison unit comparing the rectified hall voltage with a reference voltage and converting the corresponding voltage into a digital signal; and
a latch for buffering the digital signal.

5. The hall integrated circuit of claim 4, wherein the comparison unit includes a Schmitt trigger.

6. The hall integrated circuit of claim 4, wherein the comparison unit includes a comparator.

7. The hall integrated circuit of claim 6, further comprising:
a clock generating unit; and
a polarity determining unit for determining the polarity of the magnetic field on the basis of a reference clock generated by the clock generating unit.

8. The hall integrated circuit of claim 7, wherein the polarity determining unit includes:
a magnetism-pulse converting module generating a pulse signal by a propagation delay on the basis of the reference clock, the power supply voltage, and a first hall voltage and a second hall voltage of the hall device; and
a polarity determining module determining the polarity of the magnetic field on the basis of any one of a first voltage generated from the first hall voltage and a second voltage generated from the second hall voltage and the pulse signal and the reference clock.

9. The hall integrated circuit of claim 8, wherein the magnetism-pulse converting module includes:
a first module generating the first voltage from the reference clock, the power supply voltage, and the first hall voltage;
a second module generating the second voltage from the reference clock, the power supply voltage, and the second hall voltage; and
an XOR operator XOR-operating the first voltage and the second voltage.

10. The hall integrated circuit of claim 9, wherein the first module includes:
a first inverter receiving the power supply voltage and outputting an inverted voltage according to a reference clock;
a first switch turned on by applying the first hall voltage; and
a first capacitor generating the first voltage by repeating charging and discharging according to the reference clock, and
the second module includes:
a second inverter receiving the power supply voltage and outputting the inverted voltage according to the reference clock;
a second switch turned by applying the second hall voltage; and
a second capacitor generating the second voltage by repeating charging and discharging according to the reference clock.

11. The hall integrated circuit of claim 10, wherein the polarity determining module includes:
an AND operator AND-operating any one of the first voltage and the second voltage and the pulse signal; and
an SR flip-flop generating a polarity signal which is set according to an output of the AND operator and reset according to the reference clock.

12. The hall integrated circuit of claim 4, wherein a reference voltage of the comparison unit is controllable through a control terminal for user convenience.
